(19) United States
(12) Patent Application Publication
(10) Pub. No.: US 2025/0107043 A1
(43) Pub. Date: Mar. 27, 2025

(54) VAPOR CHAMBER, RADIATOR AND ELECTRONIC DEVICE

(71) Applicant: ZTE CORPORATION, Shenzhen (CN)

(72) Inventors: Zhen SUN, Shenzhen (CN); Xiaoxue CHEN, Shenzhen (CN); Zhiwei DUAN, Shenzhen (CN); Qingsong XU, Shenzhen (CN)

(21) Appl. No.: 18/730,899

(22) PCT Filed: Feb. 13, 2023
(86) PCT No.: PCT/CN2023/075573

§ 371 Date: Jul. 22, 2024

(30) Foreign Application Priority Data
Jun. 29, 2022 (CN) 202210750928.6

(51) Int. Cl. H05K 7/20

(52) U.S. Cl. CPC H05K 7/20336; H05K 7/20309

(57) ABSTRACT

Disclosed are a vapor chamber, a radiator and an electronic device. The vapor chamber includes: a bottom plate, a top plate, a side plate and a backflow piece. The bottom plate includes a first heat dissipation area and a second heat dissipation area provided at a peripheral side of the first heat dissipation area. The first heat dissipation area is provided with at least a first capillary structure layer on the side near the top plate, and the second heat dissipation area is provided with at least a second capillary structure layer on the side near the top plate. The capillary force of the first capillary structure layer is greater than that of the second capillary structure layer, and the flow resistance of the fluid medium in the second capillary structure layer is smaller than that in the first capillary structure layer.

### CROSS-REFERENCES TO RELATED APPLICATIONS

This application is a U.S. National Phase application of International Application No. PCT/CN2023/075573, filed on Feb. 13, 2023, which claims priority to Chinese Patent Application NO. 202210750928.6, filed on Jun. 29, 2022.

### TECHNICAL FIELD

The present application relates to the technical field of heat dissipation for electronic devices, and in particular, to a vapor chamber, a radiator and an electronic device.

### BACKGROUND

At present, IC chips are the core of computing in electronic devices and one of the main heating components of electronic devices. With the development of 5G communication technology, communication products are pursuing large capacity and high performance. In particular, some multi-functional IC chips are becoming more and more integrated, causing the power consumption and heat flow density of IC chips to continue to rise, posing severe challenges to heat dissipation technology.

At present, liquid cooling technology is not yet mature, and chip heat dissipation problems mainly rely on air-cooling heat dissipation technology to solve, and vapor chamber heat dissipation technology is the key technology for air-cooling heat dissipation. A vapor chamber (VC) mainly includes a shell, a capillary structure and a working medium (also called fluid medium). The VC forms a closed cavity. The inside of the cavity is evacuated and filled with the working medium, which causes the working medium to undergo phase change and transfer heat.

However, the traditional vapor chamber has poor heat dissipation effect, which makes it impossible to dissipate heat from the heating components of the electronic device in time when the electronic device is working, causing the electronic device to generate excessive heat.

### SUMMARY

The main purpose of the embodiments of the present application is to provide a vapor chamber, a radiator and an electronic device, and to provide a vapor chamber that can effectively conduct and dissipate heat to a heating element.

In a first aspect, an embodiment of the present application provides a vapor chamber, including:
a bottom plate including a first heat dissipation area and a second heat dissipation area provided at a peripheral side of the first heat dissipation area, where the first heat dissipation area is configured to correspond to a heating element;
a top plate spaced apart from the bottom plate;
a side plate, where the side plate is configured to surround a peripheral side of the second heat dissipation area of the bottom plate and connect the bottom plate and the top plate, and the bottom plate, the top plate and the side plate are enclosed to form an evaporation cavity for accommodating a fluid medium; and
a backflow piece provided in the evaporation cavity, where the backflow piece is configured to connect the bottom plate and the top plate;
the first heat dissipation area is provided with at least a first capillary structure layer on a side close to the top plate, the second heat dissipation area is provided with at least a second capillary structure layer on a side close to the top plate, the first capillary structure layer has a capillary force greater than a capillary force of the second capillary structure layer, and a flow resistance of the fluid medium in the second capillary structure layer is smaller than a flow resistance of the fluid medium in the first capillary structure layer.

In a second aspect, an embodiment of the present application provides a radiator, including a heat dissipation structure and the vapor chamber as described above, and the heat dissipation structure is connected to the vapor chamber.

In a third aspect, an embodiment of the present application provides an electronic device, including the radiator as described above.

The present application provide a vapor chamber, a radiator and an electronic device. The vapor chamber includes: a bottom plate, a top plate, a side plate and a backflow piece. The bottom plate includes a first heat dissipation area and a second heat dissipation area provided at a peripheral side of the first heat dissipation area. The first heat dissipation area is provided corresponding to the heating element. The top plate is spaced apart from the bottom plate. The side plate surrounds the peripheral side of the second heat dissipation area and connects the bottom plate and the top plate. The bottom plate, the top plate and the side plate are enclosed to form an evaporation cavity for accommodating a fluid medium. The backflow piece is provided in the evaporation cavity and connects the bottom plate and the top plate. The first heat dissipation area is provided with at least a first capillary structure layer on the side near the top plate, and the second heat dissipation area is provided with at least a second capillary structure layer on the side near the top plate. The capillary force of the first capillary structure layer is greater than that of the second capillary structure layer, and the flow resistance of the fluid medium in the second capillary structure layer is smaller than that in the first capillary structure layer. In the embodiment of the present application, two different capillary structures are provided on the bottom plate, the first capillary structure layer can improve the capillary force and heat conduction efficiency, and the second capillary structure layer can reduce the backflow resistance of the condensed liquid, therefore, the transmission efficiency of the vapor chamber is improved, and the heat dissipation problem of the vapor chamber in high power consumption and high heat flow density chip application scenarios is solved.

### BRIEF DESCRIPTION OF THE DRAWINGS

In order to illustrate the technical solutions of the embodiments of the present application more clearly, accompanying drawings needed to be used in the description of the embodiments will be briefly described below. Obviously, the accompanying drawings in the following description are some embodiments of the present application. For those skilled in the art, other drawings can also be obtained based on these drawings without creative efforts.

FIG. 1 is a schematic structural diagram of a vapor chamber according to an embodiment of the present application.

FIG. 2A and FIG. 2B are schematic diagrams of a second capillary structure layer provided in the vapor chamber according to an embodiment of the present application.

FIG. 3A is a top structural diagram of a bottom plate of the vapor chamber according to an embodiment of the present application.

FIG. 3B to FIG. 3E are schematic cross-sectional structural diagrams of a groove in the trench capillary structure when the capillary structure in the vapor chamber according to an embodiment of the present application is a trench capillary structure.

FIG. 4 is a schematic structural diagram of a modification of the vapor chamber according to an embodiment of the present application.

FIG. 5 is a schematic structural diagram of another modification of the vapor chamber according to an embodiment of the present application.

FIG. 6 is a schematic structural diagram of a radiator according to an embodiment of the present application.

FIG. 7 is a schematic structural block diagram of an electronic device according to an embodiment of the present application.

### DETAILED DESCRIPTION OF THE EMBODIMENTS

The technical solutions in the embodiments of the present application will be clearly and completely described below with reference to the accompanying drawings. Obviously, the described embodiments are some rather than all of the embodiments of the present application. Based on the embodiments in the present application, all other embodiments obtained by those skilled in the art without creative efforts fall within the scope of the present application.

The flowcharts shown in the accompanying drawings are only examples and do not necessarily include all contents and operations/steps, nor are they necessarily performed in the order described. For example, some operations/steps can also be decomposed, combined or partially merged, so the actual order of execution may change according to actual conditions.

It should be noted that the terms used in the embodiments of the present application are only for the purpose of describing specific embodiments and are not intended to limit the present application. As used in the embodiments and the appended claims, the singular forms “a”, “the” and “this” are intended to include the plural forms as well, unless the context clearly dictates otherwise. It should be understood that the term “and/or” as used herein refers to and includes any or all possible combinations of one or more of the associated listed items.

At present, IC chips are the core of computing in electronic devices and one of the main heating components of electronic devices. With the development of 5G communication technology, communication products are pursuing large capacity and high performance. In particular, some multi-functional IC chips are becoming more and more integrated, causing the power consumption and heat flow density of IC chips to continue to rise, posing severe challenges to heat dissipation technology.

At present, liquid cooling technology is not yet mature, and chip heat dissipation problems mainly rely on air-cooling heat dissipation technology to solve, and vapor chamber heat dissipation technology is the key technology for air-cooling heat dissipation. A vapor chamber (VC) mainly includes a shell, a capillary structure and a working medium (also called a fluid medium). The VC forms a closed cavity. The inside of the cavity is evacuated and filled with the working medium, which causes the working medium to undergo phase change and transfer heat.

However, the traditional vapor chamber has poor heat dissipation effect, which makes it impossible to dissipate heat from the heating components of the electronic device in time when the electronic device is working, causing the electronic device to generate excessive heat.

Based on this, the present application provides a vapor chamber, a radiator and an electronic device, aiming to provide a vapor chamber that can effectively conduct and dissipate heat to a heating element, so that the heating element can be dissipated heat in a timely manner when the electronic device is working, thereby preventing the electronic device from overheating and causing malfunctions or accidents.

Some embodiments of the present application will be described in detail below with reference to the accompanying drawings. The following embodiments and features in the embodiments can be combined with each other if there is no conflict.

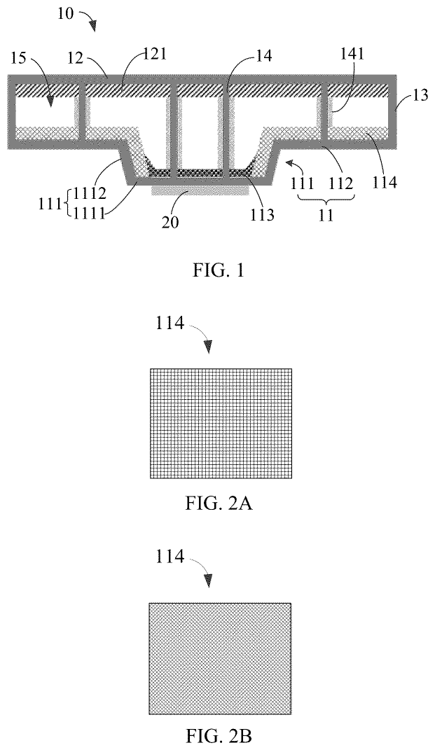

Please refer to FIG. 1, which is a schematic cross-sectional structural diagram of a vapor chamber according to an embodiment of the present application.

As shown in FIG. 1, the vapor chamber 10 is configured to adapt to a heating element 20 to dissipate heat from the heating element 20. The vapor chamber 10 includes a bottom plate 11, a top plate 12, a side plate 13 and a backflow piece 14. The bottom plate 11 includes a first heat dissipation area 111 and a second heat dissipation area 112 provided at a peripheral side of the first heat dissipation area 111. The first heat dissipation area 111 is provided corresponding to the heating element 20. The top plate 12 is spaced apart from the bottom plate 11, and the side plate 13 surrounds a peripheral side of the second heat dissipation area 112 of the bottom plate 11 and connects the bottom plate 11 and the top plate 12. The bottom plate 11, the top plate 12 and the side plates 13 are enclosed to form an evaporation cavity 15 for accommodating a fluid medium, and the fluid medium includes at least one of water, propanol, acetone, fluoride, ammonia or ethanol.

The first heat dissipation area 111 provided corresponding to the heating element 20 can be configured such that the first heat dissipation area 111 is attached to the heating element 20, or the first heat dissipation area 111 is connected to the heating element 20 through a connection medium. The connection medium includes, but is not limited to, adhesives such as thermally conductive silicone grease. Multiple backflow pieces 14 are provided, which are provided at intervals in the evaporation cavity 15, connect the bottom plate 11 and the top plate 12 to support the top plate 12, and provide a drainage path for the fluid medium to return from the top plate 12 to the bottom plate 11.

The first heat dissipation area 111 is provided with at least a first capillary structure layer 113 on a side close to the top plate 12, and the second heat dissipation area 112 is provided with at least a second capillary structure layer 114 on the side close to the top plate 12. The capillary force of the first capillary structure layer 113 is greater than the capillary force of the second capillary structure layer 114, and the flow resistance of the fluid medium in the second capillary structure layer 114 is small than the flow resistance in the first capillary structure layer 113. The heating element 20 includes, but is not limited to, an IC chip.

The fluid medium in the embodiment of the present application can also be other working media that can undergo phase changes, as long as the working medium can undergo corresponding physical state changes by absorbing heat and releasing heat.

In the embodiment of the present application, the bottom plate 11 and the side plate 13 can be integrally formed, for example, through stamping, molding, or casting. Alternatively, the bottom plate 11 and the side plate 13 can be formed separately and then fixedly connected by welding, which is not limited here.

In this embodiment, by providing the first capillary structure layer 113 in the first heat dissipation area 111 of the bottom plate 11 and the second capillary structure layer 114 in the second heat dissipation area 112 of the bottom plate 11, since the capillary structure has a pore structure and the pore structure will generate a strong capillary force, all the fluid medium injected into the evaporation cavity 15 is adsorbed in these pore structures. When the heating element 20 starts to work, the heating element 20 starts to generate heat, and heats the fluid medium in the pore structure of the first capillary structure layer 113 covered by the first heat dissipation area 111 above the heating element 20, so that the temperature of the fluid medium starts to rise.

When the temperature rises above the evaporation temperature of the fluid medium itself, the fluid medium changes from a liquid state to a vapor state. Because the vapor state fluid medium is not restricted by the structure, the fluid medium can fill the entire evaporation cavity 15. When the fluid medium in the pore structure of the first capillary structure layer 113 covered by the first heat dissipation area 111 above the heating element 20 is reduced, due to capillary action, the fluid medium in the pore structure of the second capillary structure layer 114 covered by the second heat dissipation area 112 outside the heating element 20 corresponding to the bottom plate 11 will be pulled into the first heat dissipation area 111 corresponding to the heating element 20, and the newly added fluid medium will continue to absorb the heat generated by the heating element 20, and continue to heat up and evaporate.

When the steam hits the top plate 12 of the vapor chamber 10, the external air or the external heat dissipation structure can take away part of the heat so that the temperature of the steam will drop rapidly. When the temperature drops below the condensation temperature of the fluid medium, the steam is condensed into liquid state. The fluid medium in the liquid state is returned to the bottom plate 11 of the vapor chamber 10 through the backflow piece 14, and in this cycle, the heat of the heating element 20 is continuously and efficiently transferred and dissipated into the air.

In an embodiment, based on the fact that the capillary force of the first capillary structure layer 113 is greater than the capillary force of the second capillary structure layer 114, the attractive force of the first heat dissipation area 111 located on the bottom plate 11 to the fluid medium is greater than that of the second heat dissipation area 112 to the fluid medium. Based on the fact that the flow resistance of the fluid medium in the first capillary structure layer 113 is greater than the flow resistance of the fluid medium in the second capillary structure layer 114, it is easier for the fluid medium to stay on the first heat dissipation area 111 and condense. The resulting fluid medium can more easily flow from the second heat dissipation area 112 to the first heat dissipation area 111, thereby improving the heat conduction efficiency of the first heat dissipation area 111 and realizing the heat dissipation of the heating element 20 by the vapor chamber 10.

At least one of the bottom plate 11, the top plate 12 or the side plate 13 of the vapor chamber 10 is provided with a liquid injecting opening communicated with the evaporation cavity 15. The evaporation cavity 15 can be evacuated through the liquid injecting opening, and a preset amount of fluid medium is added into the evaporation cavity 15 through the liquid injecting opening. After the fluid medium is injected, the liquid injecting opening is sealed. The liquid injecting opening can be sealed by a sealing member, or by electric welding, cold welding or ultrasonic welding, which is not limited here.

As shown in FIG. 1, in some embodiments, the first heat dissipation area 111 includes a core area 1111 and a connection area 1112. The core area 1111 is provided corresponding to the heating element 20. For example, the core area 1111 is attached to the heating element 20, or the core area 1111 is connected to the heating element 20 through a connection medium. The connection area 1112 is provided around the core area 1111 and connected to the second heat dissipation area 112.

The first capillary structure layer 113 at least partially covers the core area 1111. A distance between the core area 1111 and the top plate 12 is a first distance, and the distance between the second heat dissipation area 112 and the top plate 12 is a second distance. The first distance is greater than the second distance.

In some embodiments, the first capillary structure layer 113 and the second capillary structure layer 114 both cover the connection area 1112. When the first capillary structure layer 113 and the second capillary structure layer 114 both cover the connection area 1112, the second capillary structure layer 114 is provided on a surface of the connection area 1112, and the first capillary structure layer 113 partially covers the second capillary structure layer 114. For example, the second capillary structure layer 114 is provided on the surface of the connection area 1112, and the first capillary structure layer 113 covers 10% to 90% of the area on the side of the second capillary structure layer 114 close to the core area 1111.

Since the flow resistance of the fluid medium in the first capillary structure layer 113 is greater than the flow resistance of the fluid medium in the second capillary structure layer 114, covering the connection area 1112 with the second capillary structure layer 114 facilitates the fluid medium, after condensation, to flow more easily from the second heat dissipation area 112 to the first heat dissipation area 111.

In some embodiments, the first capillary structure layer 113 includes a capillary structure formed by sintering at least one of metal powder and diamond powder, and the metal powder includes, but is not limited to, at least one of copper powder, gold powder, and silver powder.

The second capillary structure layer 114 includes at least one of a copper mesh structure layer, a trench structure layer, a thermally conductive fiber layer, and a nanofiber layer. The second heat dissipation area 112 can be covered with the second capillary structure layer 114 through processes such as sintering, welding, and etching.

Referring to FIG. 2A and FIG. 2B, for example, when the second capillary structure layer 114 is a copper mesh structure layer, copper wires in the copper mesh structure can be arranged in a staggered array of multiple copper wires. For example, multiple copper wires are staggered in an orthogonal array, as shown in FIG. 2A, or multiple copper wires are arranged in a diagonal and staggered array at an angle, as shown in FIG. 2B.

In an embodiment, the copper mesh of the copper mesh structure layer can be a single layer of copper mesh, or a multi-layer copper mesh stacked at different angles, which is not limited here.

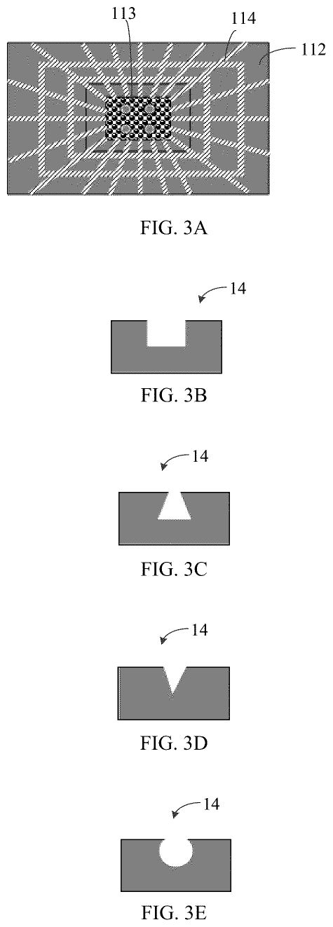

Referring to FIG. 3A, for example, the case where the second capillary structure layer 114 is a trench structure layer is described as an example. A trench structure is provided on the side of the second heat dissipation area 112 close to the top plate 12. The trench structure includes a first groove radiating outward with the first heat dissipation area 111 as a center and a second groove connecting two adjacent first grooves. By communicating the first groove with the second groove, it can effectively help the condensed liquid to flow back to the first heat dissipation area 111. The shapes of the first groove and the second groove can be any one of polygonal, arc-shaped, circular or special-shaped structures, or at least a combination of the two, which is not limited here.

As shown in FIG. 3B to FIG. 3E, the shape of any one of the first groove and/or the second groove is a triangle, a rectangle, a trapezoid, or an arc.

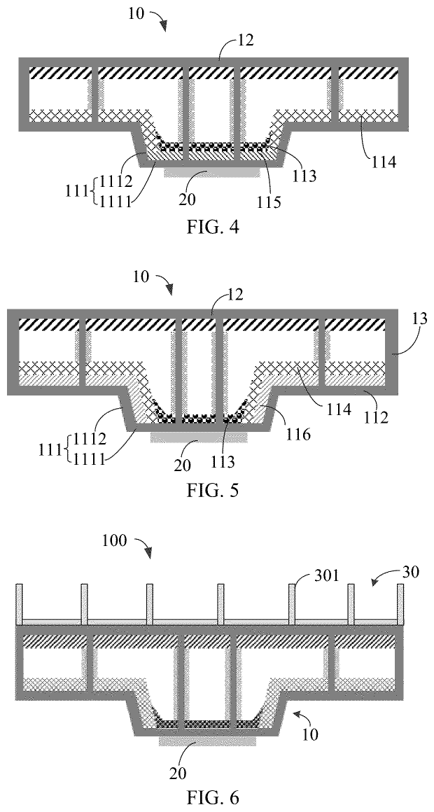

Please refer to FIG. 4, in some embodiments, the core area 1111 is also covered with a third capillary structure layer 115. The third capillary structure layer 115 is provided on the surface of the core area 1111, and the first capillary structure layer is provided on the side of the third capillary structure layer 115 close to the top plate 12. The flow resistance of the fluid medium in the third capillary structure layer 115 is smaller than the flow resistance of the fluid medium in the first capillary structure layer 113.

In an embodiment, the third capillary structure layer 115 includes at least one of a copper mesh structure layer, a thermally conductive fiber layer, a nanofiber layer, and a trench structure layer.

Since the flow resistance of the fluid medium in the third capillary structure layer 115 is smaller than the flow resistance of the fluid medium in the first capillary structure layer 113, covering the core area 1111 with the third capillary structure layer 115 facilitates the fluid medium, after condensation, to flow more easily from the second heat dissipation area 112 to the first heat dissipation area 111.

Please refer to FIG. 5, in some embodiments, the second heat dissipation area 112 and the connection area 1112 are also provided with a fourth capillary structure layer 116, and the fourth capillary structure layer 116 is provided on the surfaces of the second heat dissipation area 112 and the connection area 1112. The second capillary structure layer 114 is provided on the surface of the fourth capillary structure layer 116. The flow resistance of the fluid medium in the fourth capillary structure layer 116 is smaller than the flow resistance of the fluid medium in the second capillary structure layer 114.

Since the flow resistance of the fluid medium in the fourth capillary structure layer 116 is smaller than the flow resistance in the second capillary structure layer 114, covering the second heat dissipation area 112 and the connection area 1112 with the fourth capillary structure layer 116 facilitates the fluid medium, after condensation, to flow more easily from the second heat dissipation area 112 to the first heat dissipation area 111.

In an embodiment, the fourth capillary structure layer 116 includes at least one of a copper mesh structure layer, a thermally conductive fiber layer, a nanofiber layer, and a groove structure layer.

In an embodiment, the fourth capillary structure layer 116 is a trench structure layer, and the second capillary structure layer 114 is a copper mesh structure layer.

As shown in FIG. 1, in some embodiments, a fifth capillary structure layer 121 is provided on the side of the top plate 12 close to the bottom plate 11, and/or a sixth capillary structure layer 141 is provided on the surface of the backflow piece 14.

In an embodiment, the flow resistance of the fluid medium in the fifth capillary structure layer 121 and the sixth capillary structure layer 141 is smaller than the flow resistance in the first capillary structure layer 113.

For example, the fifth capillary structure layer 121 includes at least one of a copper mesh structure layer, a trench structure layer, a thermally conductive fiber layer, a nanofiber layer, and a capillary structure formed by powder sintering. The sixth capillary structure layer 141 includes at least one of a copper mesh structure layer, a trench structure layer, a thermally conductive fiber layer, a nanofiber layer, and a capillary structure formed by powder sintering.

For example, the case where the capillary structure layer is provided on the surfaces of the top plate 12 and the backflow piece 14 is described as an example.

Based on the fact that capillary structure layers are provided on the surfaces of the top plate 12 and the backflow piece 14, when the steam hits the top plate 12 of the vapor chamber 10 and is condensed into a liquid state, the capillary structure layer provided on the bottom plate 11 will pull the liquid state fluid medium adhered to the surface of the top plate 12 and the backflow piece 14 back to the bottom plate 11 of the vapor chamber 10 through the capillary force. That is, the capillary structure layer is provided on the surfaces of the backflow piece 14 and the top plate 12, which is beneficial for the condensed fluid medium to return to the bottom plate 11.

In some embodiments, an inner surface of the side plate 13 is also provided with a seventh capillary structure layer. The seventh capillary structure layer includes any one of a copper mesh structure layer, a groove structure layer, a thermally conductive fiber layer, a nanofiber layer, and a capillary structure formed by powder sintering. Please refer to FIG. 6, the present application also provides a radiator 100 for dissipating heat from the heating element 20. The radiator 100 includes a heat dissipation structure 30 and a vapor chamber 10 connected to the heat dissipation structure 30. The structure of the vapor chamber 10 can refer to any of the previous embodiments, and will not be described again here.

In an embodiment, the heat dissipation structure 30 is connected to the top plate 12 of the vapor chamber 10 for dissipating heat from the vapor chamber 10. For example, the heat dissipation structure 30 is provided with a plurality of spaced heat dissipation fins 301. The spaced arrangement of the heat dissipation fins 301 can increase the contact area between the heat dissipation structure 30 and the air, thereby facilitating heat dissipation of the vapor chamber 10.

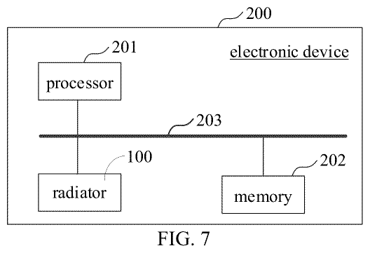

Referring to FIG. 7, the present application also provides an electronic device 200. The electronic device 200 includes a processor 201, a memory 202 and a radiator 100. The processor 201 and the memory 202 are connected through a bus 203. The bus is, for example, inter-integrated circuit (I2C) bus, and the radiator 100 is configured to dissipate heat from the processor 201.

In an embodiment, the processor 201 is configured to provide computing and control capabilities to support the operation of the entire electronic device 200. The processor 201 can be a central processing unit (CPU). The processor 201 can also be other general-purpose processors, digital signal processors (DSP), application specific integrated circuits (ASIC), field-programmable gate array (FPGA) or other programmable logic devices, discrete gate or transistor logic devices, discrete hardware components, etc. The general processor can be a microprocessor or the processor can be any conventional processor.

In an embodiment, the memory 202 can be a Flash chip, a read-only memory (ROM) disk, an optical disk, a USB disk, a mobile hard disk, or the like.

The electronic device 200 includes, but is not limited to, a base station, a mobile phone, a tablet computer, a notebook computer, a desktop computer, a personal digital assistant, a wearable device, etc.

It should be understood that the term “and/or” as used in this specification and the appended claims refers to and includes any and all possible combinations of one or more of the associated listed items. It should be noted that, as used herein, the terms “include”, “comprise” or any other variation thereof are intended to cover a non-exclusive inclusion, such that a process, method, article or system that includes a list of elements not only includes those elements, but also includes other elements not expressly listed or that are inherent to the process, method, article or system. Without further limitation, an element defined by the statement “include a . . . ” does not exclude the presence of other identical elements in the process, method, article, or system that includes that element.

In the above embodiments, each embodiment is described with its own emphasis. For parts that are not described in detail in a certain embodiment, please refer to the relevant descriptions of other embodiments.

The above serial numbers of the embodiments of the present application are only for description and do not represent the advantages or disadvantages of the embodiments. The above are only specific embodiments of the present application, but the scope of the present application is not limited thereto. Those skilled in the art can easily think of various equivalent modifications or replacements within the scope of the present application, and these modifications or replacements shall be covered by the scope of the present application. Therefore, the scope of the present application should be subject to the scope of the claims.

1. A vapor chamber, comprising:
a bottom plate comprising a first heat dissipation area and a second heat dissipation area provided at a peripheral side of the first heat dissipation area, wherein the first heat dissipation area is configured to correspond to a heating element;
a top plate spaced apart from the bottom plate;
a side plate, wherein the side plate is configured to surround a peripheral side of the second heat dissipation area of the bottom plate and connect the bottom plate and the top plate, and the bottom plate, the top plate and the side plate are enclosed to form an evaporation cavity for accommodating a fluid medium; and
a backflow piece provided in the evaporation cavity, wherein the backflow piece is configured to connect the bottom plate and the top plate;
wherein the first heat dissipation area is provided with at least a first capillary structure layer on a side close to the top plate, the second heat dissipation area is provided with at least a second capillary structure layer on a side close to the top plate, the first capillary structure layer has a capillary force greater than a capillary force of the second capillary structure layer, and a flow resistance of the fluid medium in the second capillary structure layer is smaller than a flow resistance of the fluid medium in the first capillary structure layer.

2. The vapor chamber of claim 1, wherein the first heat dissipation area comprises a core area and a connection area, the core area is configured to correspond to the heating element, and the connection area is provided at a peripheral side of the core area and is connected to the second heat dissipation area; and
wherein the first capillary structure layer is configured to cover at least a part of the core area, a distance between the core area and the top plate is a first distance, a distance between the second heat dissipation area and the top plate is a second distance, and the first distance is greater than the second distance.

3. The vapor chamber of claim 2, wherein both the first capillary structure layer and the second capillary structure layer are configured to cover the connection area, and in response to that both the first capillary structure layer and the second capillary structure layer cover the connection area, the second capillary structure layer is provided on a surface of the connection area, and the first capillary structure layer partially covers the second capillary structure layer.

4. The vapor chamber of claim 3, wherein the core area is also covered with a third capillary structure layer, the third capillary structure layer is provided on a surface of the core area, and the first capillary structure layer is provided on a side of the third capillary structure layer close to the top plate; and
wherein a flow resistance of the fluid medium in the third capillary structure layer is smaller than the flow resistance of the fluid medium in the first capillary structure layer.

5. The vapor chamber of claim 4, wherein the first capillary structure layer comprises a capillary structure formed by sintering at least one of metal powder and diamond powder; the second capillary structure layer comprises at least one of a copper mesh structure layer, a trench structure layer, a thermally conductive fiber layer, and a nanofiber layer; and the third capillary structure layer comprises at least one of a copper mesh structure layer, a trench structure layer, a thermally conductive fiber layer, and a nanofiber layer.

6. The vapor chamber of claim 3, wherein the second heat dissipation area and the connection area are further provided with a fourth capillary structure layer, and the fourth capillary structure layer is provided on surfaces of the second heat dissipation area and the connection area, and the second capillary structure layer is provided on a surface of the fourth capillary structure layer; and
wherein a flow resistance of the fluid medium in the fourth capillary structure layer is smaller than the flow resistance of the fluid medium in the second capillary structure layer.

7. The vapor chamber of claim 1, wherein a fifth capillary structure layer is provided on a side of the top plate close to the bottom plate; and/or a sixth capillary structure layer is provided on a surface of the backflow piece.

8. The vapor chamber of claim 1, wherein the fluid medium comprises at least one of water, propanol, acetone, fluoride, ammonia liquid or ethanol.

9. A radiator, comprising a heat dissipation structure and the vapor chamber of claim 1, wherein the heat dissipation structure is connected to the vapor chamber.

10. An electronic device, comprising the radiator of claim 9.
